(19) United States
(12) Patent Application Publication
(10) Pub. No.: US 2012/0073630 A1
(43) Pub. Date: Mar. 29, 2012

(54) RECTANGULAR PROTECTIVE FRAME FOR SOLAR CELL MODULE

(75) Inventors: Woei-Yuan WU, Taoyuan (TW); Chun-Yi Lee, Taoyuan (TW)

(73) Assignee: Perfect Source Technology Corp., Taoyuan (TW)

(21) Appl. No.: 12/891,955

(22) Filed: Sep. 28, 2010

(51) Int. Cl. H01L 31/048

(52) U.S. Cl. 136/251

(57) ABSTRACT

A rectangular protective frame for a solar cell module is disclosed. The rectangular protective frame for a solar cell module includes: four bar elements, each including: a supporting portion, having an L-shape cross-section, encompassing edges of the solar cell module for supporting the solar cell module; and a body portion, having a rectangular cross-section with a long side connected to the supporting portion for increasing strength of the supporting portion. The rectangular protective frame also includes at least one carrying mechanism, connected to a short side of the body portion of at least one of the four bar elements, having an L-shape cross-section, for preventing fingers from slipping off while carrying the rectangular protective frame.

### FIELD OF THE INVENTION

The present invention relates generally to a rectangular protective frame for a solar cell module. More specifically, the present invention relates to an improved rectangular protective frame having a carrying mechanism for preventing fingers from slipping off while carrying the rectangular protective frame.

### BACKGROUND OF THE INVENTION

Among the recent world consciousness of ecological and environmental protection issues, the deepest concern is directed to the warming of the earth by CO₂ production, and the development and stable supply of clean energy are urgently desired objectives. The solar cell is one of the most promising clean energy sources because of its safety and ease of handling. According to the state-of-the-art technology and requirements in the market, in addition to consumer electronic products, such as mobile phones, toys and calculators, the solar cell module is used for mid-size to large-size power supplies.

The solar cell modules are often installed outside of buildings. Roofs and walls are commonly seen to equip with this kind of solar cell modules. Many types of frames for fixing the solar cell modules are disclosed in the prior arts. Please see FIG. 1. U.S. Pat. No. 5,252,141 discloses a solar cell module 1 using hooks 1a to lock into walls. Therefore, the solar cell module 1 can be fixed on the wall. This invention provides a simple frame without screws. However, it is complex in structure. Meanwhile, it is not easy to manufacture, and strength is poor.

U.S. Pat. No. 5,409,549 is shown in FIG. 2. The '549 patent provides a solar cell module frame 2 and fixing devices 2a on the wall. The two fixing devices 2a are used to fix a long trench type of solar cell module 2b on each side. The fixing devices 2a and the frame 2 are all placed on the roof. A place inside the frame 2 is used to clamp the solar cell module 2b. An Ω type fixer 2c covers the adjacent solar cell modules 2b and firms the relative position. Another trench fixer 2d is used to help fixing the frame 2 inside the Ω type fixer 2c. Waterproof effect is thus provided. In fact, this structure is also complex and expensive. In addition, the solar cell module 2b needs to have a trench structure. Application of the frame is limited.

Please refer to FIG. 3 showing another example of a prior art frame 3 which is easy to assemble and disassemble a solar cell module. Moreover, the frame 3 can be fixed on a building. Connecting wings 3a and 3b are provided on a first element 3c and a second element 3d to form the frame 3. The wings 3a and 3b are located at different height of the first element 3c and the second element 3d, respectively. When two adjacent wings 3a and 3b are connected to each other, waterproof effect is provided. The frame 3 can be used in large solar power systems. Furthermore, a pole 3e is fabricated to fix the frame 3 onto a building. The frame 3 can provide a different outer appearance for the building. It solves most shortcomings above. However, the frame 3 is inconvenient and dangerous to move and install. The frame 3 will fall inadvertently when workers move them carelessly.

In summary, conventional solar cell module frames have other functions than supporting solar cell modules. One of the pending issues for design of the frame is concern of safety when the solar cell module is moved and fixed. The present invention provides a solution to this issue. By providing a carrying mechanism, workers can grip their fingers firmly to hold the solar cell module frame for transportation. It is a very easy design but can be very helpful and applied to any current solar cell modules. Besides, the module frame can be manufactured by simple processes at low cost.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In accordance with an aspect of the present invention, a rectangular protective frame for a solar cell module includes: four bar elements, each including: a supporting portion, having an L-shape cross-section, encompassing edges of the solar cell module for supporting the solar cell module; and a body portion, having a rectangular cross-section with a long side connected to the supporting portion for increasing strength of the supporting portion. The rectangular protective frame also includes at least one carrying mechanism, connected to a short side of the body portion of at least one of the four bar elements, having an L-shape cross-section, for preventing fingers from slipping off while carrying the rectangular protective frame.

Preferably, the rectangular protective frame is made of aluminum.

Preferably, the rectangular protective frame is made by extrusion.

Preferably, the body portion includes at least one screw connecting section, having a hook shape cross-section, for screwing two adjacent bar elements together.

### BRIEF DESCRIPTION OF THE DRAWINGS

The above object and advantages of the present invention will become more readily apparent to those ordinarily skilled in the art after reviewing the following detailed description and accompanying drawings, in which:

FIG. 1 is a prior art of a solar cell module frame.

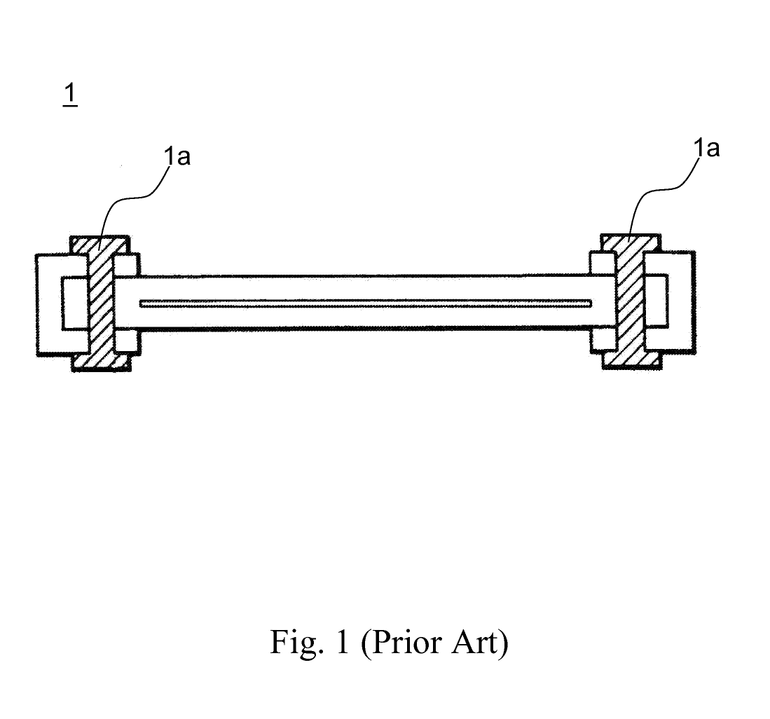

FIG. 2 is another prior art of a solar cell module frame.

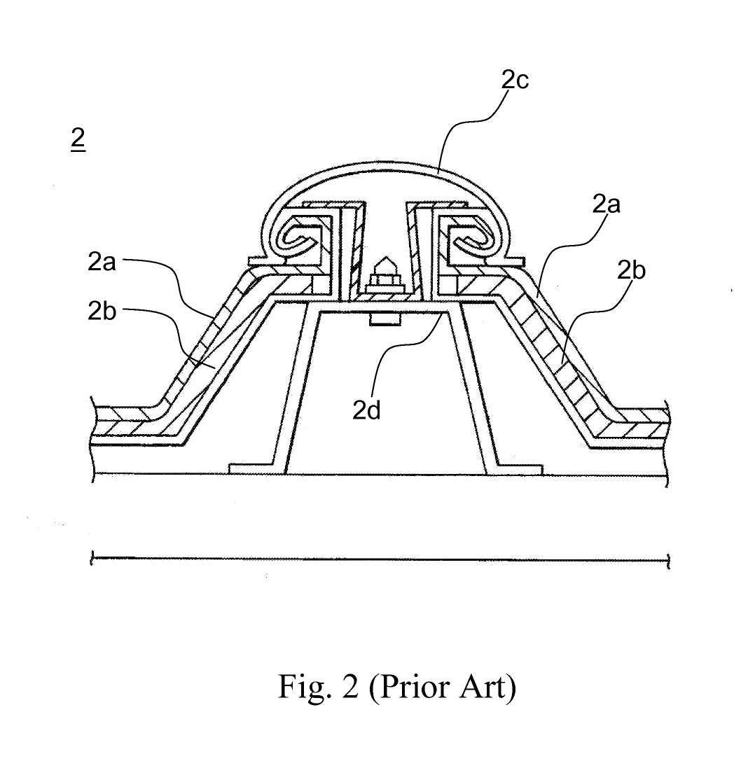

FIG. 3 is still another prior art of a solar cell module frame.

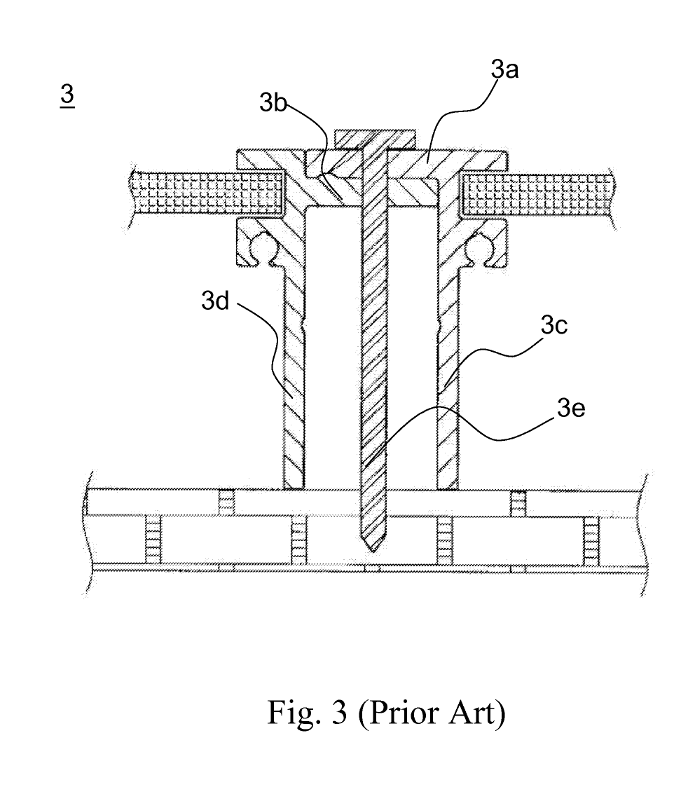

FIG. 4 is an embodiment of the present invention.

FIG. 5 is a cross-sectional view along line A-A′ in FIG. 4.

FIG. 6 is cross-sectional view of a bar element in the embodiment of the present invention.

FIG. 7 is a cross-sectional view along line B-B′ in FIG. 4.

FIG. 8 illustrates how the invention prevents falling of a solar cell module when moving.

### DETAILED DESCRIPTION OF THE PREFERRED EMBODIMENT

The present invention will now be described more specifically with reference to the following embodiment. It is to be noted that the following descriptions of the embodiment of this invention is presented herein for purpose of illustration and description only; it is not intended to be exhaustive or to be limited to the precise form disclosed.

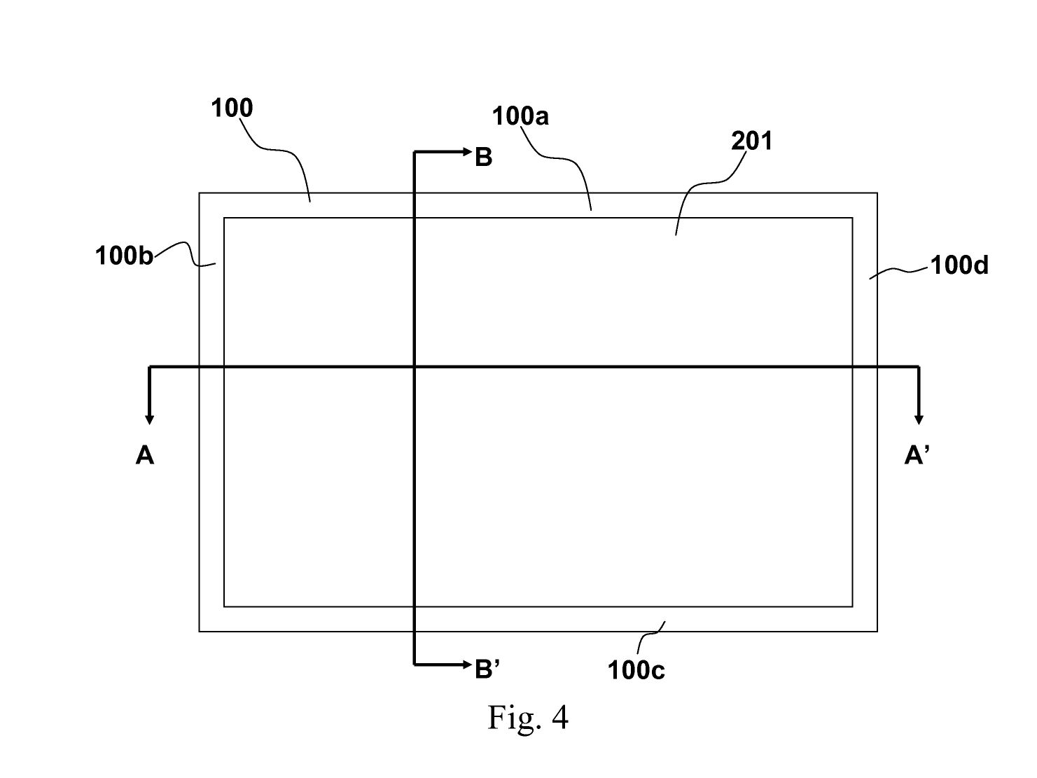

Please refer to FIG. 4. It is a top view of a rectangular protective frame 100 according to the spirit of the present invention. In this embodiment, the rectangular protective frame 100 is a combination of four bar elements 100a, 100b, 100c, and 100d. The rectangular protective frame 100 is placed around a solar cell module 201 for sustaining the solar cell module 201.

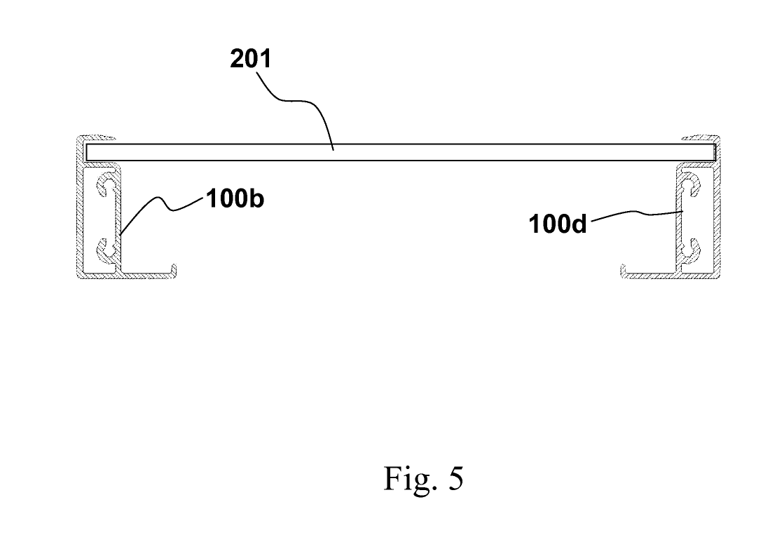

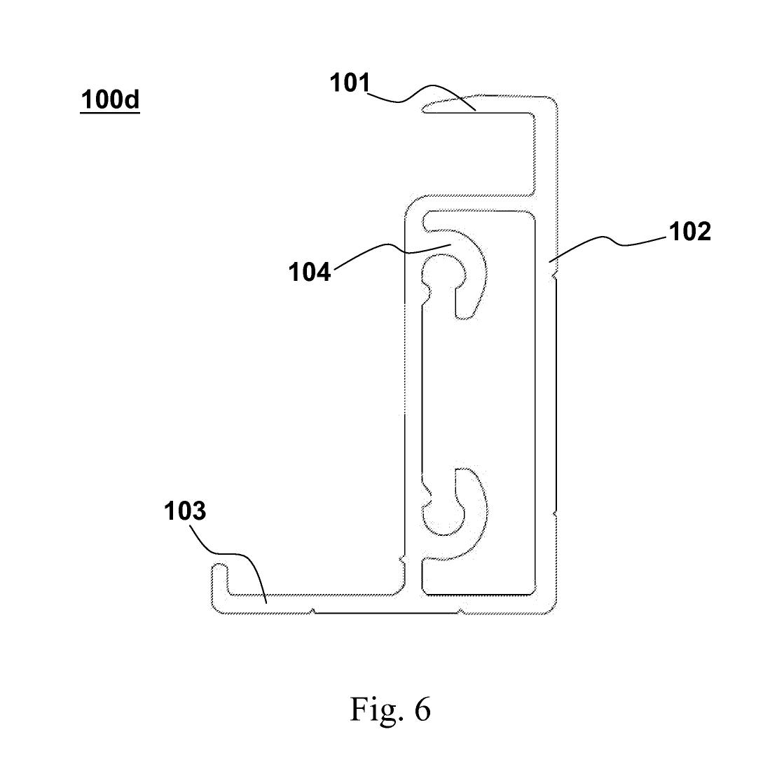

In order to have a detailed illustration of the rectangular protective frame 100, FIG. 5 shows a cross-sectional view along line A-A′ in FIG. 4. To have a closer view of one bar element 100d, please see FIG. 6. In FIG. 6, it is obvious that the bar element 100d has a supporting portion 101, a body portion 102 and a carrying mechanism 103.

The supporting portion 101 has an L-shape cross-section, encompassing edges of the solar cell module 201 for supporting the solar cell module 201. The carrying mechanism 103 also has an L-shape cross-section, for preventing fingers from slipping off while carrying.

The body portion 102 has a rectangular cross-section with a long side and a short side. The long side is connected to the supporting portion 101 for increasing strength of the supporting portion 101 and the short side is connected to the carrying mechanism 103. In this embodiment, the rectangular protective frame 100 is made by aluminum.

The carrying mechanism 103 is extended from the short side of the body portion 102. It should be noticed that the L-shape is only shown in the cross-section A-A′ in FIG. 4. The carrying mechanism 103 is used to provide a gripping position for workers for moving the rectangular protective frame 100. Fingers of the workers can hold the carrying mechanism 103 to prevent the rectangular protective frame 100 from falling.

In this embodiment, the body portion 102 has two screw connecting sections 104 having a hook shape cross-section, for screwing two adjacent bar elements together. It should be noted that the number of screw connecting sections 104 is not limited to two. According to the spirit of the present invention, the number of screw connecting sections 104 can be reduced to one in a bar element as long as the fixing effect is good. Furthermore, the screw connecting section 104 does not need to be formed on all four bar elements. For example, it can be formed on two opposite sides of the rectangular protective frame 100.

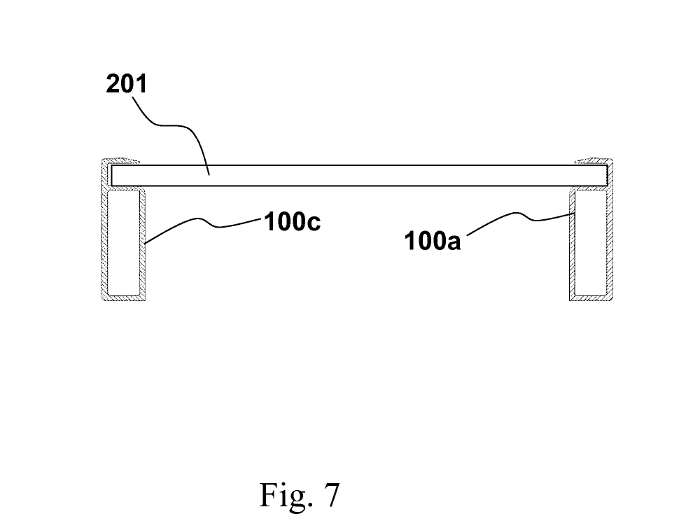

Please refer to FIG. 7 showing a cross-sectional view along line B-B′ in FIG. 4. In this embodiment, the carrying mechanism 103 and the screw connecting section 104 are only formed on two opposite sides of the rectangular protective frame 100 (i.e., bar elements 100b and 100d). Hence, differentiated from the bar elements 100b and 100d having two screw connecting sections 104 and a carrying mechanism 103, the bar elements 100a and 100c doesn't have any screw connecting sections or carrying mechanism. Whether the carrying mechanism 103 is formed on each side, two sides, or only one side of the rectangular protective frame 100 depends on the size and weight of the solar cell module 201. Preferably, the carrying mechanism 103 is formed on two opposite sides as described in the present embodiment since the rectangular protective frame 100 usually takes two workers to carry. If the weight of the solar cell module 201 is light, the carrying mechanism 103 just needs to be applied to one side of the rectangular protective frame 100.

Because the material of the rectangular protective frame 100 is aluminum, the rectangular protective frame 100 can be made by extrusion method. Of course, the four sides of the rectangular protective frame 100 can be made by separately welding individual pieces if the material used is harder than aluminum. Connections between the bar elements 100a, 100b, 100c and 100d are not limited to screwing. Any two adjacent sides of the rectangular protective frame 100 which don't have the screw connecting section 104 can be connected by corner fitting, gluing or welding.

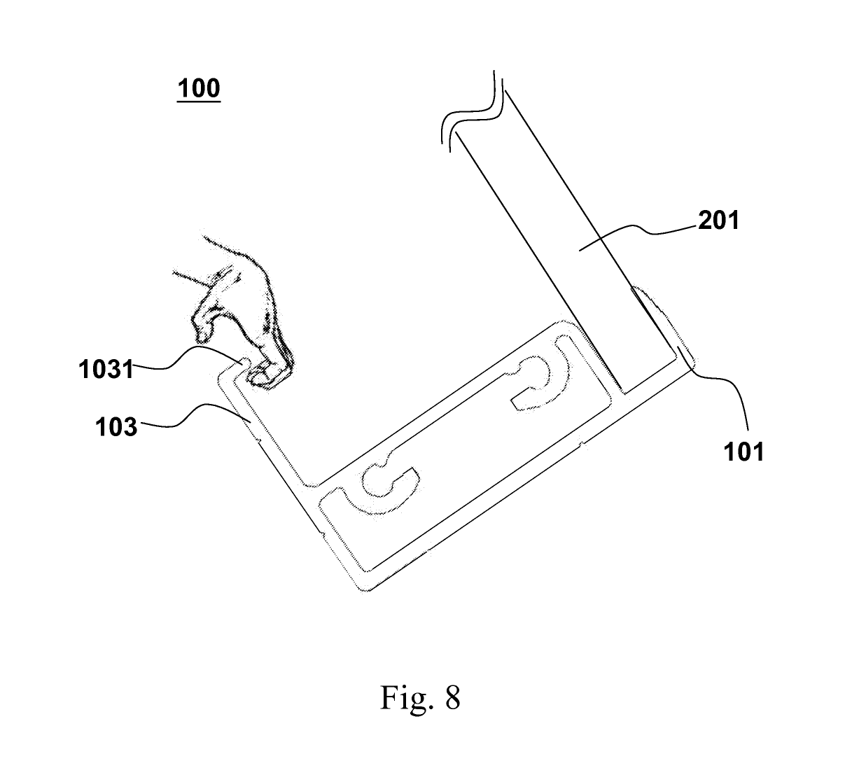

Please refer to FIG. 8. It should be emphasized that direction of an end 1031 of the carrying mechanism 103 is perpendicular to the supporting portion 101. The design of the carrying mechanism 103 can make workers carry the rectangular protective frame 100 with the solar cell module 201 easily and won't touch the solar cell module 201. It can be seen that as long as the fingers are bended and hold the carrying mechanism 103, the rectangular protective frame 100 won't fall to the ground.

While the invention has been described in terms of what is presently considered to be the most practical and preferred embodiment, it is understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A rectangular protective frame for a solar cell module, comprising:
four bar elements, each including:
a supporting portion, having an L-shape cross-section, encompassing edges of the solar cell module for supporting the solar cell module; and
a body portion, having a rectangular cross-section with a long side connected to the supporting portion for increasing strength of the supporting portion;
and
at least one carrying mechanism, connected to a short side of the body portion of at least one of the four bar elements, having an L-shape cross-section, for preventing fingers from slipping off while carrying the rectangular protective frame.

2. The rectangular protective frame according to claim 1, wherein the rectangular protective frame is made of aluminum.

3. The rectangular protective frame according to claim 1, wherein the rectangular protective frame is made by extrusion.

4. The rectangular protective frame according to claim 1, wherein the body portion includes at least one screw connecting section, having a hook shape cross-section, for screwing two adjacent bar elements together.
